(19) United States
(12) Patent Application Publication
(10) Pub. No.: US 2017/0112015 A1
(43) Pub. Date: Apr. 20, 2017

(54) SERVER

(71) Applicant: BEIJING BAIDU NETCOM SCIENCE AND TECHNOLOGY CO., LTD., Beijing (CN)

(72) Inventors: Sheng KANG, Beijing (CN); Guofeng CHEN, Beijing (CN); Wei WEI, Beijing (CN); Yongzhong ZHU, Beijing (CN); Jie WANG, Beijing (CN)

(21) Appl. No.: 14/900,011

(22) PCT Filed: Dec. 10, 2014
(86) PCT No.: PCT/CN2014/093520

§ 371 Date: Dec. 18, 2015

(30) Foreign Application Priority Data
Jul. 4, 2014 (CN) 201410318162.X

(51) Int. Cl. H05K 7/14; G06F 1/26

(52) U.S. Cl. CPC H05K 7/1487; G06F 1/266; H05K 7/1492; H05K 7/1498

(57) ABSTRACT

The present invention provides a server, including a casing; and at least one single server node of the server, disposed in the casing and comprising a hard disk of a first size, a drawout hard disk tray, a hard disk backplane, a mainboard and a node power distributing board, in which the hard disk of the first size is disposed on the drawout hard disk tray and at least two layers of the drawout hard disk trays are provided; each layer of the drawout hard disk tray is connected to the hard disk backplane via a retractable cable, or, each layer of the drawout hard disk tray is connected to the mainboard and the node power distributing board via the retractable cable, and the drawout hard disk tray is configured to perform a hot swap of the hard disk of the first size.

### CROSS REFERENCE TO RELATED APPLICATION

This application claims priority of Chinese Patent Application No. 201410318162.X, filed by Baidu Online Network Technology (Beijing) Co., LTD. with State Intellectual Property Office on Jul. 4, 2014, the entire content of which is incorporated herein by reference.

### FIELD

Embodiments of the present invention generally relate to a server field, and more particularly, to a server.

### BACKGROUND

With developments of computing world and increase of data volume, respective enterprises have increasingly improved requirements of a server. Currently, most servers are designed in a height of 1 U, 2 U and in a 19-inch cabinet' width (448 mm). In order to achieve a hot swap of a hard disk, the hard disks are connected together via their backplanes and each hard disk is arranged in a single layer.

However, the conventional server has low space utilization.

### SUMMARY

Embodiments of the present invention seek to solve at least one of the problems existing in the related art to at least some extent.

An objective of the present invention is to provide a server, which has high space utilization.

In order to achieve the above objective, embodiments of the present invention provide a server, including: a casing; and at least one single server node of the server, disposed in the casing and including a hard disk of a first size, a drawout hard disk tray, a hard disk backplane, a mainboard and a node power distributing board, in which the hard disk of the first size is disposed on the drawout hard disk tray and at least two layers of the drawout hard disk trays are provided; each layer of the drawout hard disk tray is connected to the hard disk backplane via a retractable cable, or, each layer of the drawout hard disk tray is connected to the mainboard and the node power distributing board via the retractable cable, and the drawout hard disk tray is configured to perform a hot swap of the hard disk of the first size.

With the server according to embodiments of the present invention, by disposing the hard disk on the drawout hard disk tray and providing at least two layers of the drawout hard disk trays, space in the server can be fully used so as to improve the space utilization. Furthermore, the hot swap of the hard disk on each layer of the drawout hard disk tray can be obtained by connecting each layer of the drawout hard disk tray to the hard disk backplane via the retractable cable, or, to the mainboard and the node power distributing board via the retractable cable.

Additional aspects and advantages of embodiments of present invention will be given in part in the following descriptions, become apparent in part from the following descriptions, or be learned from the practice of the embodiments of the present invention.

### BRIEF DESCRIPTION OF THE DRAWINGS

Above and/or additional aspects and advantages of embodiments of the present invention will become apparent and more readily appreciated from the following descriptions made with reference to the accompanying drawings, in which:

FIG. 1 is a schematic view of a server according to an embodiment of the present invention;

FIG. 2 is a schematic view showing locations of a power pack and a centralized power management board according to an embodiment of the present invention;

FIG. 3 is a schematic view of a single server node according to an embodiment of the present invention;

FIG. 4 is another schematic view of a single server node according to an embodiment of the present invention;

FIG. 5 is another schematic view of a single server node according to an embodiment of the present invention;

FIG. 6 is a schematic view of a primary tray of a single serve node according to an embodiment of the present invention; and

FIG. 7 is a schematic view of a power pack and a centralized power management board according to an embodiment of the present invention.

### DETAILED DESCRIPTION

Reference will be made in detail to embodiments of the present invention. Embodiments of the present invention will be shown in drawings, in which the same or similar elements and the elements having same or similar functions are denoted by like reference numerals throughout the descriptions. The embodiments described herein according to drawings are explanatory and illustrative, not construed to limit the present invention. Instead, the embodiments of the present invention comprise all the variants, modifications and their equivalents within the spirit and scope of the present invention as defined by the claims.

A server according to embodiments of the present invention will be described in the following with reference to drawings.

FIG. 1 is a schematic view of a server according to an embodiment of the present invention. As shown in FIG. 1, the server includes a casing 11 and at least one single server node 12 of the server. The at least one single server node 12 is disposed in the casing 11.

The at least one single server node 12 may be arranged in different regions of the server.

Specifically, as shown in FIG. 1, taking an example in which the server is in a height of 2 U, two single server nodes of the server may be provided and arranged at left and right sides of the server respectively.

Specifically, the single server node 12 includes a hard disk of a first size, a drawout hard disk tray, a hard disk backplane, a mainboard and a node power distributing board.

The hard disk of the first size is disposed on the drawout hard disk tray and at least two layers of the drawout hard disk trays are provided.

Each layer of the drawout hard disk tray is connected to the hard disk backplane via a retractable cable, or, each layer of the drawout hard disk tray is connected to the mainboard and the node power distributing board via the retractable cable, and the drawout hard disk tray is configured to perform a hot swap of the hard disk of the first size.

With the server according to embodiments of the present invention, by disposing the hard disk on the drawout hard disk tray and providing at least two layers of the drawout hard disk trays, space in the server can be fully used so as to improve space utilization. Furthermore, the hot swap of the hard disk on each layer of the drawout hard disk tray can be obtained by connecting each layer of the drawout hard disk tray to the hard disk backplane via the retractable cable, or, to the mainboard and the node power distributing board via the retractable cable.

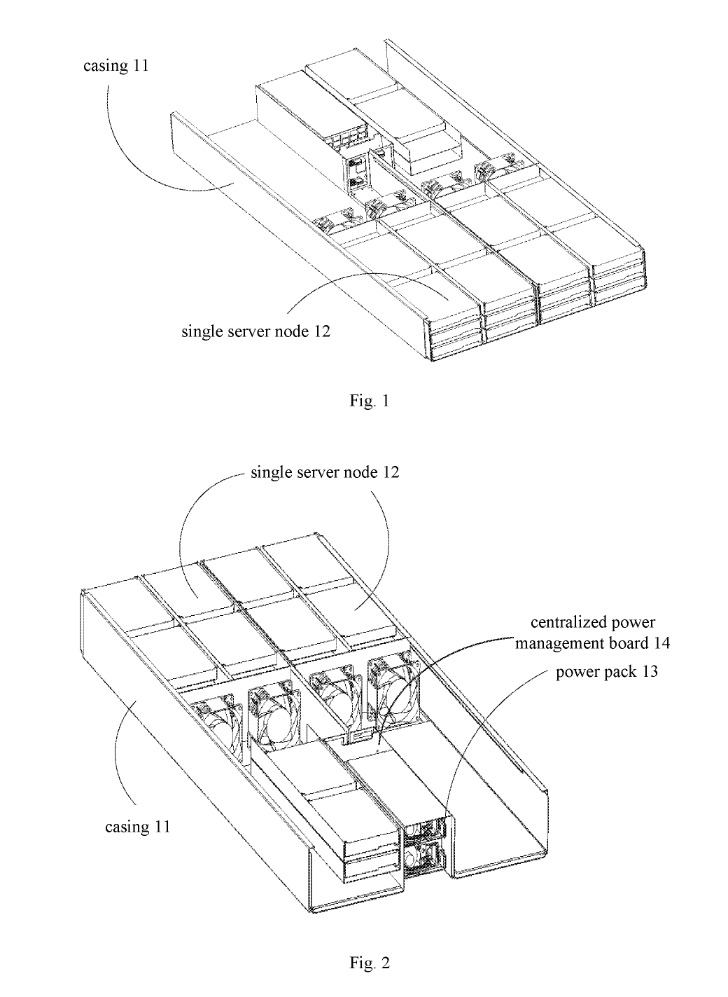

Furthermore, as shown in FIG. 2, the server according to embodiments of the present invention further includes a power pack 13 and a centralized power management board 14. The power pack 13 and the centralized power management board 14 are disposed within the server and configured to provide centralized power supply with the two single server nodes. Compared with a technical solution in which a power source arranged at side in the related art, in the embodiment, when the power pack 13 is pulled out, the hard disk will not interfere with a power distributing unit (PDU) and a node cable in a rear portion of the cabinet.

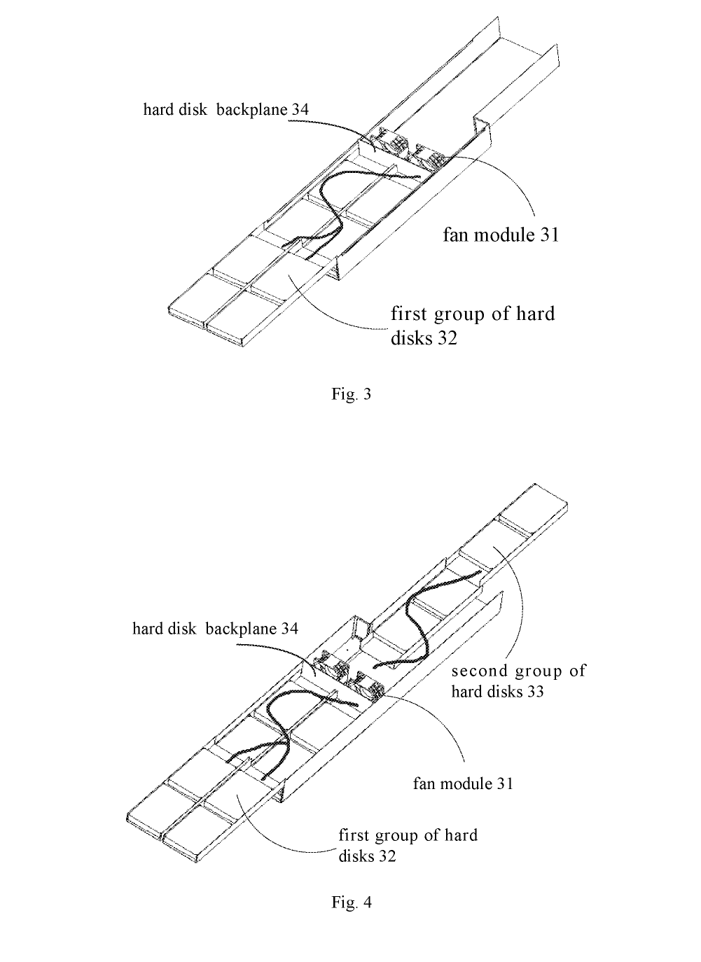

Taking the single server node as an example, in an embodiment, as shown in FIG. 3, the single server node includes a fan module 31 and a hard disk of a first size. The hard disk of the first size includes a first group of hard disks 32 disposed in front of the fan module 31.

Specifically, the hard disk of the first size may be configured as a 3.5-inch hard disk.

Optionally, the fan module 31 includes at least one fan. In particular, two fans are provided as shown in FIG. 3, and each fan has a size of 80 mm×38 mm. Redundancy can be obtained by setting the two fans. Specifically, by setting the two fans, 1+1 redundancy can be realized so as to improve heat dissipation reliability.

Certainly, it may be understood that the single server node may further include a power transfer board, a CPU and a memory.

Optionally, as shown in FIG. 3, the first group of hard disks 32 are disposed on a first group of drawout hard disk trays. In the embodiment, the first group of drawout hard disk trays includes three layers of drawout hard disk trays, at most four hard disks of the first size are disposed on each layer of the drawout hard disk tray, and thus twelve hard disks can be arranged in one server node. Furthermore, each layer of the drawout hard disk tray in the first group is connected to the hard disk backplane via a retractable cable, or, each layer of the drawout hard disk tray in the first group is connected to the mainboard and the node power distributing board via the retractable cable, so that each layer of the drawout hard disk tray in the first group can be pulled out with the retractable cable and continue operating without being powered off, thus obtaining a hot swap. As shown in FIG. 3, for example, each layer of the drawout hard disk tray in the first group is connected to the hard disk backplane 34 via the retractable cable.

As shown in FIG. 3, a mainboard space is formed in rear of the fan module 31 and the single server node has a height of 2 U, so that a CPU cooling fin having a height of 2 U can be achieved, thus realizing the heat dissipation with high performance.

In the embodiment, the 3.5-inch hard disks are arranged in three layers and at most four 3.5-inch hard disks are disposed in each layer, so that the space utilization of the server is improved, thus improving server density and memory density greatly. In addition, the space in rear of the fan may be used to dissipate heat so as to obtain the heat dissipation with high performance, thus optimizing the heat dissipation and reducing power consumption of the fan.

In an embodiment, as shown in FIG. 4, the hard disk of the first size in the single sever node further includes a second group of hard disks 33 disposed in rear of the fan module 31.

The second group of hard disks 33 are disposed on a second group of drawout hard disk trays. The second group of drawout hard disk trays include at least two layers of drawout hard disk trays, and at most four hard disks of the first size are disposed in each layer of the drawout hard disk tray.

As shown in FIG. 4, for example, the second group of hard disks are disposed in two layers of drawout hard disk trays and each layer of the drawout hard disk tray contains two hard disks. It may be understood that the second group of hard disks may be arranged in a transverse direction, so that four hard disks may be disposed in each layer of drawout hard disk tray.

Each layer of the drawout hard disk tray in the second group is connected to the hard disk backplane via the retractable cable, or, each layer of the drawout hard disk tray in the second group is connected to the mainboard and the node power distributing board via the retractable cable, so that each layer of the drawout hard disk tray in the second group can be pulled out with the retractable cable and continue operating without being powered off, thus obtaining the hot swap.

A mainboard having low power consumption, such as a Jbod card or a CPU card having low power consumption may be disposed below or in front of the second group of drawout hard disk trays.

In the embodiment, by arranging the 3.5-inch hard disks in at least two layers in rear of the fan and disposing at most four 3.5-inch hard disks in each layer, the space utilization of the server is further improved and the server density and the memory density are further improved.

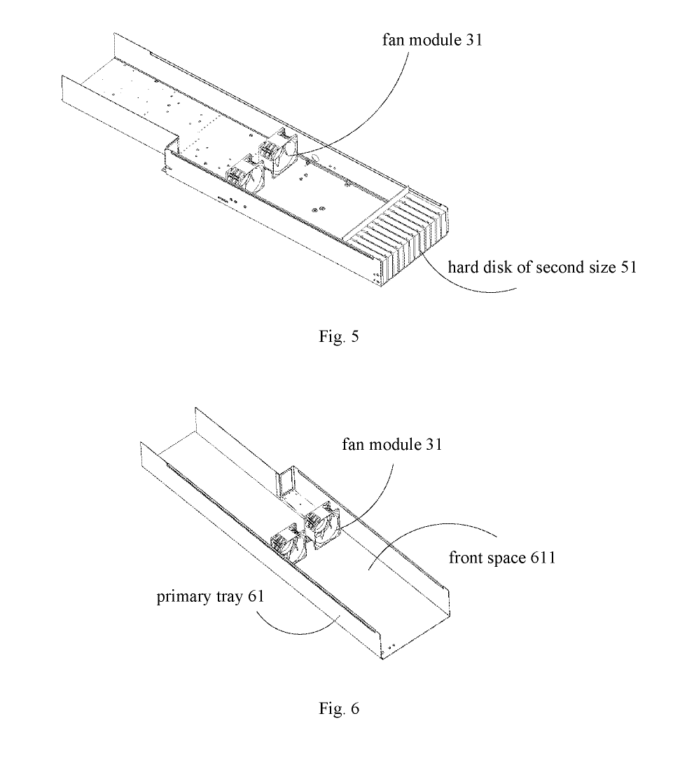

In an embodiment, as shown in FIG. 5, the server node includes a hard disk of a second size 51 disposed in a vertical insertion manner.

Specifically, the hard disk of the second size 51 is configured as a 2.5-inch hard disk.

Optionally, as shown in FIG. 5, the server node in the embodiment further includes the fan module 31. In an embodiment, the fan module 31 includes at least one fan. In particular, two fans are provided as shown in FIG. 5, and each fan has a size of 80 mm×38 mm. Furthermore, by setting the two fans, 1+1 redundancy can be realized so as to improve heat dissipation reliability.

The hard disk of the second size 51 is located in front of the fan module 31 and disposed in the vertical insertion manner, which allows for the hot swap of at most twelve hard disks of the second size 51. as shown in FIG. 5, the mainboard space is formed in rear of the fan module 31 and the single server node has a height of 2 U, so that the CPU cooling fin having a height of 2 U can be achieved, thus realizing the heat dissipation with high performance.

In the embodiment, by disposing the 2.5-inch hard disk in the vertical insertion manner and allowing for the hot swap of at most twelve 2.5-inch hard disks, the space utilization of the server is improved, and the server density and memory density are improved greatly. In addition, the space in rear of the fan may be used to dissipate heat so as to obtain the heat dissipation with high performance, thus optimizing the heat dissipation and reducing the power consumption of the fan.

In an embodiment, as shown in FIG. 6, the single server node is disposed in a corresponding primary tray 61, and different sub trays may be disposed in the primary tray 61 so as to alter different arrangements. For example, the hard disk of the first size is disposed in a first sub tray, and the hard disk of the second size is disposed in a second sub tray. When the hard disk of the first size needs to be disposed in front of the fan module 31, the first sub tray may be disposed in a front space 611 of the primary tray 61; when the hard disk of the second size needs to be disposed in front of the fan module 31, the second sub tray may be disposed in the front space 611 of the primary tray 61.

In the embodiment, the single server node is arranged in the primary tray, and different portions of the single server node are located in different sub trays, so that different configurations of the server can be obtained by replacing the sub tray, thus realizing a flexible change of the server configuration.

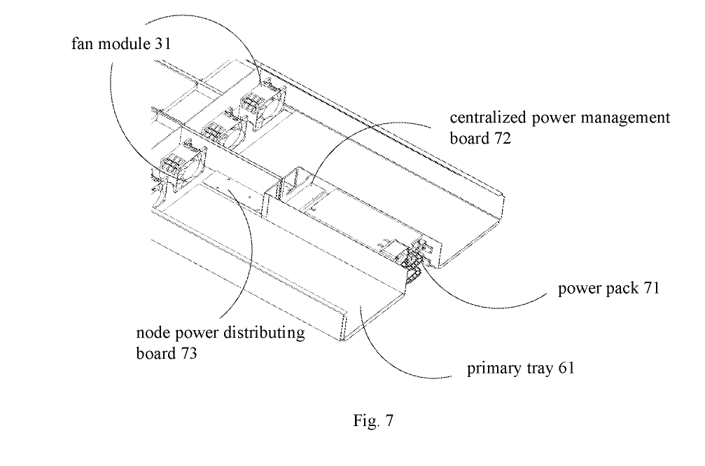

In an embodiment, as shown in FIG. 7, the server further includes a power pack 71 and a centralized power management board 72.

The power pack 71 is configured to provide power.

Specifically, as shown in FIG. 7, the power pack 71 includes at least one power source. When a plurality of power source is provided, a redundancy design can be obtained. For example, if two power sources are provided, a 1+1 redundancy power design can be obtained, and the power sources are located in middle.

The centralized power management board 72 is connected with the power pack 71 and the node power distributing board 73 of the single server node, and configured to perform a centralized power distribution and management on the single server node according to the power provided by the power pack.

Specifically, when the single server nodes are arranged in a left and right direction, the centralized power management board provides a centralized power supply to the single server nodes arranged in the left and right direction.

The node power distributing board 73 is corresponding to the single server node, connected with the centralized power management board 72 and configured to perform the power distribution and management on the single server node corresponding to the node power distributing board.

For example, the node power distributing board 73 at a left side is configured to supply power to the single server node at the left side and the node power distributing board 73 at a right side is configured to supply power to the single server node at the right side.

In the embodiment, the power sources are arranged in middle, so as to realize the centralized power supply. Compared with a technical solution in which the power source is arranged at side in the related art, in the embodiment, when being pulled out, the hard disk will not interfere with a power distributing unit (PDU) and a node cable in a rear portion of the cabinet. In addition, with the redundancy power design, the reliability of the power source can be improved.

It should be noted that, terms such as “first” and “second” are used herein for purposes of description and are not intended to indicate or imply relative importance or significance. Furthermore, in the description of the present invention, “a plurality of relates to two or more than two.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present invention. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present invention. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present invention, and changes, alternatives, and modifications can be made in the embodiments without departing from spirit, principles and scope of the present invention.

1. A server, comprising:
a casing; and
at least one single server node of the server, disposed in the casing and comprising a hard disk of a first size, a drawout hard disk tray, a hard disk backplane, a mainboard and a node power distributing board,
wherein the hard disk of the first size is disposed on the drawout hard disk tray and at least two layers of the drawout hard disk trays are provided;
each layer of the drawout hard disk tray is connected to the hard disk backplane via a retractable cable, or, each layer of the drawout hard disk tray is connected to the mainboard and the node power distributing board via the retractable cable, and the drawout hard disk tray is configured to realize a hot swap of the hard disk of the first size.

2. The server according to claim 1, wherein
the single server node further comprises: a fan module; and
the hard disk of the first size in the single sever node comprises: a first group of hard disks disposed in front of the fan module.

3. The server according to claim 2, wherein
the first group of hard disks are disposed on three layers of drawout hard disk trays, and at most four hard disks of the first size are disposed on each layer of the drawout hard disk trays.

4. The server according to claim 2, wherein
the hard disk of the first size in the single sever node further comprises: a second group of hard disks disposed in rear of the fan module.

5. The server according to claim 4, wherein
the second group of hard disks are disposed on at least two layers of drawout hard disk trays, and at most four hard disks of the first size are disposed in each layer of the drawout hard disk trays.

6. The server according to claim 4, wherein
the single server node further comprises: a Jbod card or a CPU card having low power consumption, and the second group of hard disks are disposed above or behind the Jbod card or the CPU card having low power consumption.

7. The server according to claim 2, wherein the fan module includes at least one fan.

8. The server according to claim 1, wherein the hard disk of the first size is configured as a 3.5-inch hard disk.

9. The server according to claim 1, wherein
the single server node comprises: a hard disk of a second size disposed in a vertical insertion manner.

10. The server according to claim 9, wherein the hard disk of the second size is configured as a 2.5-inch hard disk.

11. The server according to claim 9, wherein the single server node is disposed in a corresponding primary tray, the hard disk of the first size is disposed in a first sub tray, the hard disk of the second size is disposed in a second sub tray, and the first sub tray or the second sub tray is disposed in the primary tray.

12. The server according to claim 1, wherein more than one single server node are provided and disposed in different regions of the server, respectively.

13. The server according to claim 12, wherein on the condition two single server nodes are provided in the server, the two nodes are disposed at left and right sides of the server, respectively.

14. The server according to claim 1, further comprising:
a power pack, configured to provide power; and
a centralized power management board, connected with the power pack and with the node power distributing board of the single server node, and configured to perform a centralized power distribution and management on the single server node according to the power provided by the power pack,
wherein the node power distributing board is configured to perform the power distribution and management on the single server node corresponding to the node power distributing board.

15. The server according to claim 14, wherein the power pack comprises at least one power source.

16. The server according to claim 14, wherein the power pack and the centralized power management board are disposed in the server and configured to centralizedly provide power.

17. The server according to claim 6, wherein the low power consumption is in a range from 20 W to 50 W.
